(19) United States
(12) Patent Application Publication
(10) Pub. No.: US 2016/0315036 A1
(43) Pub. Date: Oct. 27, 2016

(54) DUAL TRANSISTORS FABRICATED ON LEAD FRAMES AND METHOD OF FABRICATION

(71) Applicant: Texas Instruments Incorporated, Dallas, TX (US)

(72) Inventors: Makoto Shibuya, Beppu City (JP); Dan Okamoto, Oita (JP)

(21) Appl. No.: 14/695,333

(22) Filed: Apr. 24, 2015

(51) Int. Cl. H01L 23/495; H01L 25/00; H01L 29/66; H01L 25/07; H01L 29/45; H01L 29/78

(52) U.S. Cl. CPC H01L 23/49562; H01L 23/49582; H01L 29/45; H01L 29/7827; H01L 29/66666; H01L 25/072; H01L 23/49575; H01L 23/49537; H01L 25/50

(57) ABSTRACT

A dual transistor device includes a first transistor having a first drain, a first gate, and first source and a second transistor having a second drain, a second gate, and a second source. A first terminal is substantially flat and has a first surface. The first source is located adjacent a first portion of the first surface and is electrically coupled to the first terminal. The second drain is located adjacent a second portion of the first surface and is electrically coupled to the first terminal.

### BACKGROUND

Dual transistor circuits, such as dual field-effect transistor (FETs) circuits have two transistors that are electrically connected in series, so current flows from the drain to the source of a first transistor and from the drain to the source of a second transistor. A node, referred to as the first source, second drain node or the S1, D2 node is located at the junction of the source of the first transistor and the drain of the second transistor.

The dual transistor circuits are fabricated such that the S1, D2 node is a common conductor shared by both transistors, wherein the transistors are fabricated as a single stack. In some embodiments, the source and drain nodes are lead frames, so the dual transistor configuration includes a first lead frame for the first drain, a second lead frame for the common S1, D2 node, and a third lead frame for the second source. The gates are typically fabricated from portions of the lead frames of the first drain and/or the second source. The configuration of the common S1, D2 node enables two transistors to be fabricated by the use of three lead frames.

### SUMMARY

A dual transistor device includes a first transistor having a first drain, a first gate, and first source and a second transistor having a second drain, a second gate, and a second source. A first terminal is substantially flat and has a first surface. The first source is located adjacent a first portion of the first surface and is electrically coupled to the first terminal. The second drain is located adjacent a second portion of the first surface and is electrically coupled to the first terminal.

### BRIEF DESCRIPTION OF THE DRAWINGS

FIG. 1 is a schematic diagram of two transistors electrically coupled together.

FIG. 2 is a side elevation view of an embodiment of a device with the transistors of FIG. 1 fabricated therein.

FIG. 3 is a top isometric view of the device of FIG. 2 viewed from the front.

FIG. 4 is a top isometric view of the device of FIG. 2 viewed from the rear.

FIG. 5 is a top isometric view of a first lead frame and a top isometric view of a second lead frame with the transistors of FIG. 2 being fabricated thereon.

FIG. 6 is a top isometric view of the lead frames of FIG. 5 being placed together to form the transistors and device of FIG. 2.

FIG. 7 is a flow chart illustrating an exemplary method of fabricating the transistors of FIG. 2

### DETAILED DESCRIPTION

Configurations of dual transistor devices are described herein. The dual transistor configuration is flatter than conventional configurations and provides better thermal characteristics than conventional configurations. Additionally, the dual transistor configuration is fabricated on two lead frames rather than the conventional configuration requiring three lead frames.

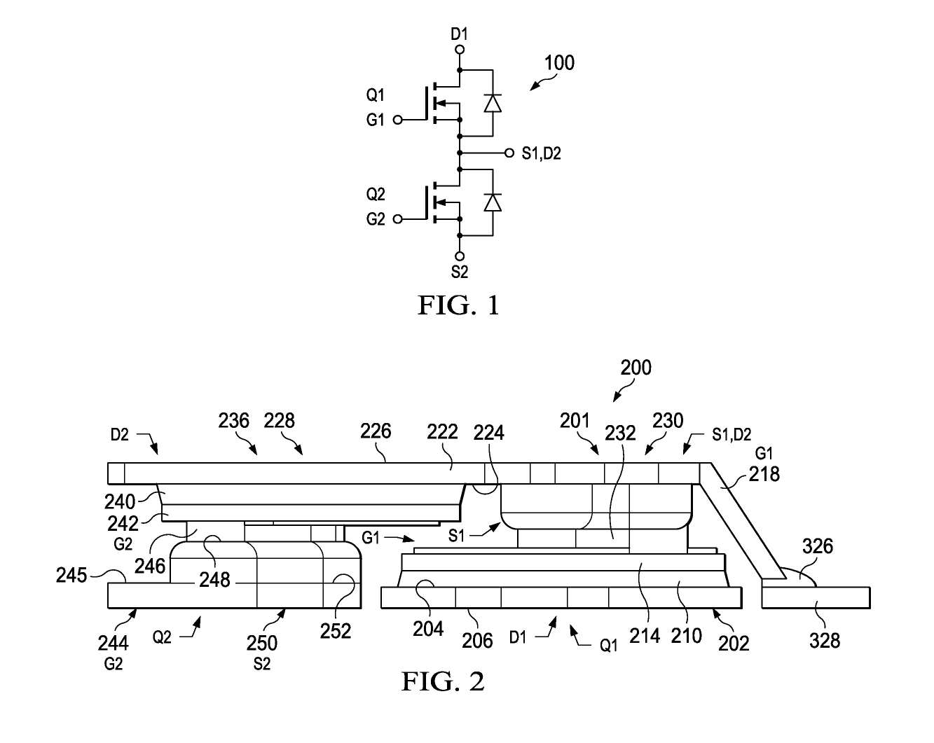

FIG. 1 is a schematic diagram of a circuit 100 consisting of two transistors, a first transistor Q1 and a second transistor Q2, coupled together in series. In the illustrative examples described herein, the transistors Q1 and Q2 are field effect transistors (FETs), however the transistor configurations described herein are applicable to other transistor types. The first transistor Q1 has a drain, a gate, and a source, which are referred to herein as the first drain D1, the first gate G1, and the first source S1. The first drain D1, the first gate G1, and the first source S1 may be electrically and/or mechanically coupled to terminals that are described below. The second transistor Q2 has a drain, a gate, and a source, which are referred to herein as the second drain D2, the second gate G2, and the second source S2. The second drain, the second gate, and the second source may also be connected to terminals that are described below. The first source S1 and the second drain D2 are connected together. For reference purposes, a single terminal for the first source S1 and the second drain D2 is referred to as the terminal S1, D2. The transistors Q1 and Q2 described herein are PNP or N-channel FETs. The transistors Q1 and Q2 may be readily replaced with NPN or P-channel FETs by substitutions of the sources and drains.

The circuit 100 has five terminals that may be connectable to external circuits and/or nodes. The first drain D1, the first gate G1, the second gate G2, and the second source S2 may all have separate terminals that are connectable to other nodes or circuits. The terminal S1,D2 has a single terminal that is connectable to an external circuit or node. In some embodiments, the circuit 100 drives a high power device and/or draws significant power, so the transistors Q1 and Q2 require heat transfer devices to keep them cool during operation of the circuit 100.

FIG. 2 is a side elevation view of an embodiment of a device 200 in which the transistors Q1 and Q2 of FIG. 1 are fabricated. The transistors Q1 and Q2 are fabricated by stacking the drain, gate, and source of each of the transistors Q1 and Q2 in adjacent stacks. A first stack 201 forms the first transistor Q1 and includes a terminal 202 that is connected to the first drain D1. The terminal 202 in the embodiment of FIG. 2 is a lead frame. As described below, the lead frame of the terminal 202 may be fabricated from the same material as the terminal for the second source S2. The terminal 202 has a first side 204 and an opposite second side 206. An electrical and mechanical bonding material 210 is located on the first surface 204 of the terminal 202 to electrically and mechanically connect the first drain Di to the first gate G1. Some examples of the bonding material 210 include solder materials such as lead tin (PbSn) and lead tin silver (PbSnAg). The same bonding materials may be used in all the portions of the device 200 where electrical and/or mechanical bonding of components is required.

The first gate G1 is fabricated from at least one gate pad material 214 that is bonded to the bonding material 210. The gate pad material 214 may include aluminum and/or aluminum silicon or other materials commonly used as gate pad materials in transistors. A gate terminal 218 is electrically coupled to the gate pad material 214 and serves to electrically connect the first gate G1 to an external circuit. Bonding material, such as solder serves to electrically and mechanically couple the gate terminal 218 to the gate pad material 214.

The first source S1 and the second drain D2 share a common terminal 222, which in the examples described herein is a lead frame, such as a copper lead frame. The terminal 222 has a first surface 224 and an opposite second surface 226. The terminal 222 has a first portion 228 that is half etched and a second portion 230 that is at least partially full. The second portion 230 has a bonding material 232 attached thereto that electrically and mechanically couples the first source S1, which is the terminal 222 to the gate pad material 214. In some embodiments, the bonding material 232 is the same material as the bonding material 210.

The second transistor Q2 is formed in a second stack 236 from the same materials as the first transistor 01, except that the second transistor Q2 is inverted relative to the first transistor Q1. The second portion 228 of the terminal 222 has the second drain D2 fabricated thereon. A bonding material 240 electrically and mechanically couples the surface 224 to a gate pad material 242, which may be the same material as the gate pad material 214. The gate pad material 242 at least partially forms the second gate G2. A second gate terminal 244 electrically couples to the gate pad material 242 and serves to electrically couple the second gate G2 to an external circuit. The gate terminal 244 has a surface 245 that may be on the same plane or approximately on the same plane as the surface 204.

A bonding material 246 electrically and mechanically couples the gate pad material 242 to the top surface 248 of a terminal 250, wherein the terminal 250 is the terminal for the second source S2. The terminal 250 proximate the second source S2 is a full lead frame and other portions of the lead frame may be half etched. The terminal 250 is sometimes referred to as having a surface 252 on which the second source S2 is fabricated. The second surface 252 may be on the same plane or approximately on the same plane as the surface 204. In some embodiments, the terminal 202, the gate terminal 244, and the terminal 250 are fabricated from the same sheet of material, such as a lead frame made of copper.

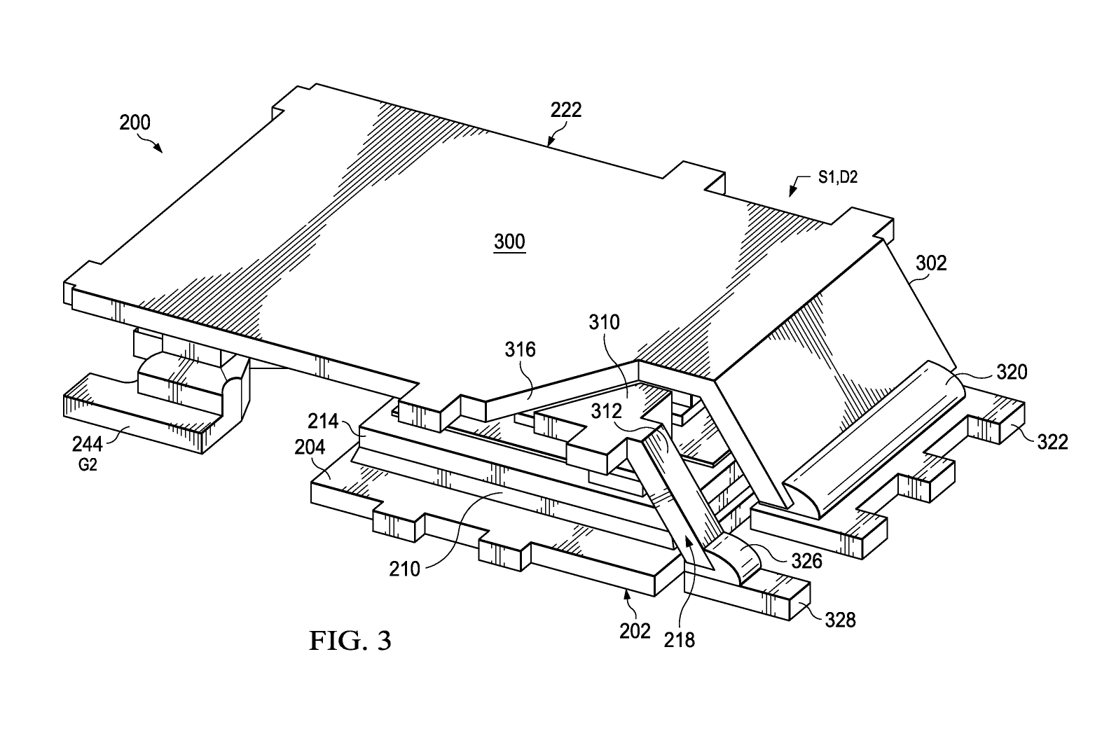

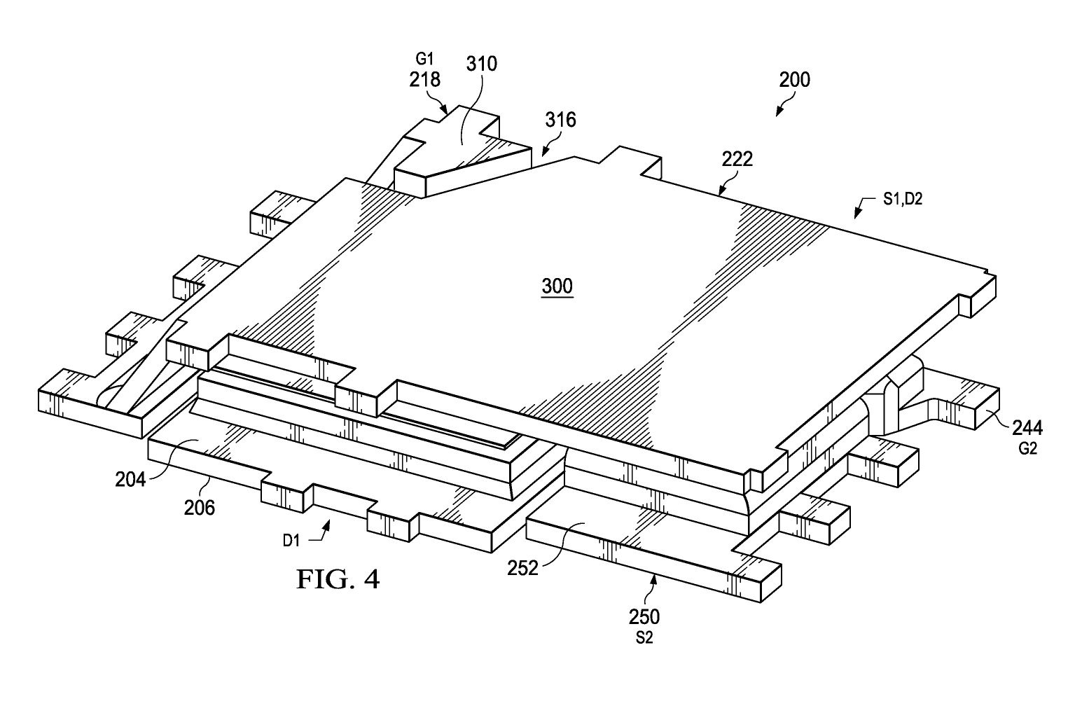

FIG. 3 is a top isometric view of the device 200 viewed from the front and FIG. 4 is a top isometric view of the device 200 viewed from the rear. As shown, the terminal 222 and the gate terminal 218 may be fabricated from the same sheet of metal, such as the same sheet of copper. The terminal 222 includes a horizontal portion 300 and an angled portion 302. The term “horizontal portion” 300 does not mean a spatial reference; rather it refers to portions of the terminal 222 where the transistors Q1 and Q2 are connected. Likewise, the gate terminal 218 includes a horizontal portion 310 and an angled portion 312 that are aligned with the same portions 300 and 302 of the terminal 222. A space 316 electrically isolates the terminal 222 from the gate terminal 218. The space 316 may be fabricated by full etching the lead frame constituting the gate terminal 218 and the terminal 222 during fabrication.

The terminal 202 of the first drain D1, the second gate terminal 244 of the second gate G2 and the terminal 250 of the second source S2 may be fabricated from the same lead frame. Spaces electrically isolate the terminals from each other and may be fabricated by full etching of the lead frame during fabrication. Both the transistors Q1 and Q2 may be fabricated from two lead frames. Conventional transistor configurations have stacked transistors, so at least three lead frames are required for fabrication. For example, a first transistor is stacked onto a second transistor, which requires lead frames on the ends of the stack and a lead frame for the common source/drain terminal between the stacked transistors.

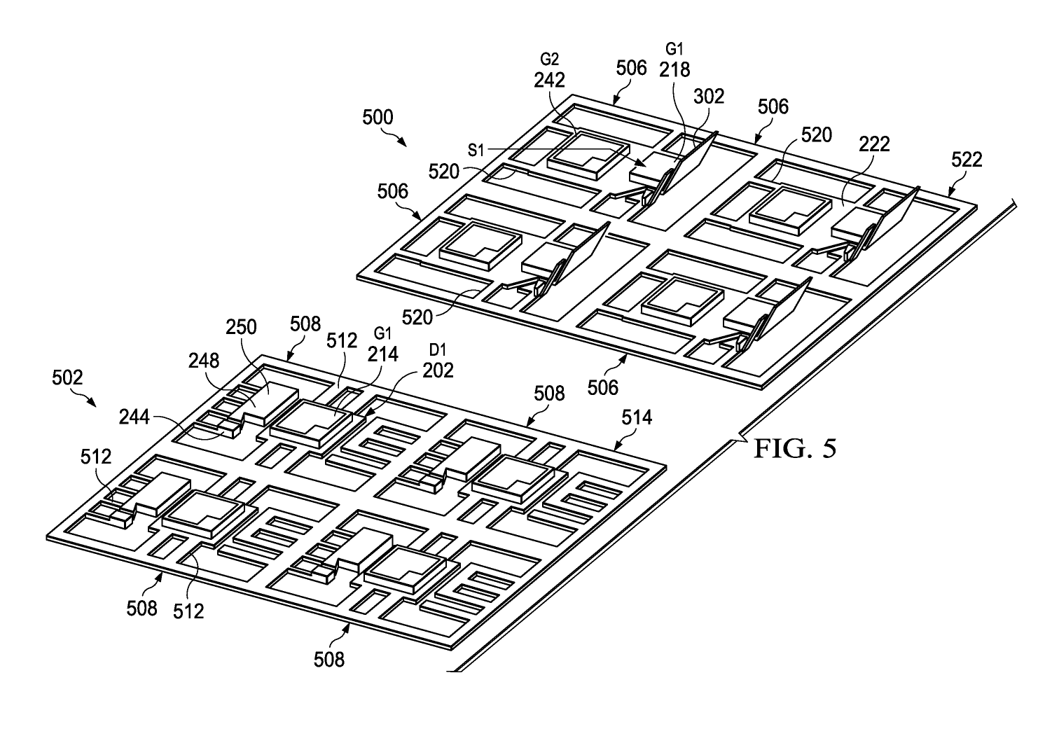

FIG. 5 is a top isometric view of a first lead frame 500 and a top isometric view of a second lead frame 502 with the transistors of FIG. 2 being fabricated thereon. The first lead frame 500 is upside down relative to the views of FIGS. 2-4. Both lead frames 500 and 502 start fabrication as single sheets of conductive material, such as copper, and are etched of otherwise fabricated to form the lead frames of FIGS. 2-4. For example, some of the lead frame portions are full, some are half etched, and some are fully etched to yield the spaces.

Each of the lead frames 500 and 502 have four sections 506 and 508 wherein one device 200 is fabricated by a combination of one of the sections 506 and one of the sections 508. The lead frames 500 and 502 may have any number of sections 506 and 508 and the example of four sections 506 and 508 shown in FIG. 5 is for illustration purposes only. The second lead frame 502 is fabricated to have the second gate terminal 244, the terminal 250, which is the second source S2, and the terminal 202, which is the first drain D1. The second lead frame 502 has a plurality of connecting members 512 that connect the terminals to a support frame 514. Accordingly, all of the terminals are maintained in a fixed position relative to the support frame 514 during fabrication. The first lead frame 500 is fabricated to have the first gate terminal 218 and the terminal 222, which is the S1, D2 terminal fabricated therein. A plurality of connecting members 520 connects the terminals to a support frame 522, so the terminals are maintained in a fixed position relative to the support frame 520 during fabrication.

The thicker portions of the lead frames 500 and 502, such as those corresponding to the sources S1 and S2 may be full lead frame thickness, meaning that no etching was performed on the lead frames 500 and 502 proximate these locations. The other portions of the lead frames 500 and 502 where metal remains may be fabricated by a half etch or similar etching wherein the thicknesses of the lead frames 500 and 502 are reduced from their original thicknesses. The spaces are areas of the lead frames 500 and 502 where the metal has been completely removed, which may be achieved by a full etch process.

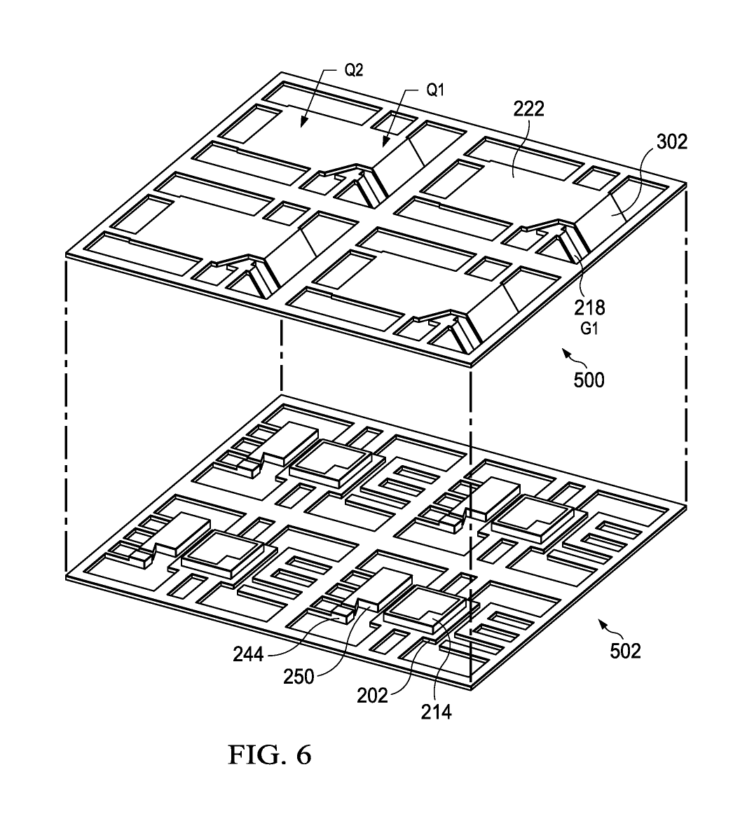

FIG. 6 is a top isometric view of the lead frames 500 and 502 of FIG. 5 being placed together to form a plurality of devices 200 of FIGS. 2-4. The bonding materials have been added to the lead frames 500 and 502 on the portions of the transistors Q1 and Q2 that require the bonding material. The two lead frames 500 and 502 are placed together to form a plurality of devices 200. The bonding materials are cured, which electrically and mechanically couples the lead frames 500 and 502 together. For example, if the bonding materials are solder pastes, they may have to be heated and cooled to be cured. Subsequent to curing, the lead frames 500 and 502 are encased in a conventional mold and then they are singulated into the individual devices 200.

With additional reference to FIGS. 2-4, the resulting device 200 has many benefits over conventional devices. The device 200 has two transistors Q1 and Q2 connected in series that are fabricated with only two lead frames 500 and 502. Conventional devices have the transistors stacked on top of each other, so the second source S2 and the first drain D1 are on separate lead frames, which requires a minimum of three lead frames. By reducing the number of lead frames required for transistor fabrication, the costs and fabrication time of the transistors Q1 and Q2 described herein is reduced relative to conventional devices.

The conventional devices with stacked transistors have one transistor on top of another, so there is very little area for heat dissipation. The transistors Q1 and Q2 described herein are located side by side so that their sources and drains are not stacked on each other. Accordingly, the terminal 222 enables greater heat dissipation from the source of the first transistor Q1 and the drain of the transistor Q2 than with conventional devices.

Other embodiments of the device 200 will now be described. Reference is made to FIGS. 2 and 3, which show a solder joint 320 connecting the angled portion 302 of the terminal 222 with a terminal 322. A similar solder joint 326 connects the gate terminal 218 to a terminal 328. The terminals 322 and 328 are on the same plane as the second lead frame 502, FIG. 5, and may be fabricated from the second lead frame 502. By locating the terminals 322 and 328 on the second lead frame, all of the terminals for the transistors Q1 and Q2 are located on the same plane, which enables easier connections to other circuits. The solder joints 320 and 326 may be the same bonding material described above and may be applied and cured with the bonding material described above when the first and second lead frames 500 and 502 are bonded together. Accordingly, the solder joints 320 and 328 do not add any significant fabrication time.

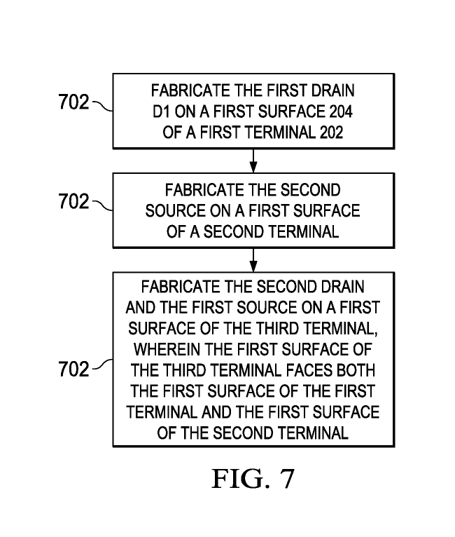

FIG. 7 is a flow chart 700 illustrating an exemplary method of fabricating the transistors Q1 and Q2 described above. Step 702 includes fabricating the first drain D1 on a first surface 204 of a first terminal 202. Step 704 includes fabricating the second source S2 on a first surface of a second terminal 250. Step 706 includes fabricating the second drain D2 and the first source S1 on a first surface 224 of a third terminal 222, wherein the first surface 224 of the third terminal 222 faces both the first surface 204 of the first terminal 202 and the first surface of the second terminal.

While some examples of transistor circuits have been described in detail herein, it is to be understood that the inventive concepts may be otherwise variously embodied and employed and that the appended claims are intended to be construed to include such variations except insofar as limited by the prior art.

1. A dual transistor device comprising:
a first transistor having a first drain, a first gate, and first source;
a second transistor having a second drain, a second gate, and a second source;
a first terminal, the first terminal being substantially flat and having a first surface;
wherein the first source is located adjacent a first portion of the first surface and is electrically coupled to the first terminal; and
wherein the second drain is located adjacent a second portion of the first surface and is electrically coupled to the first terminal.

2. The device of claim 1 wherein the first drain is fabricated on a first drain terminal having a first drain terminal surface and wherein the first drain terminal surface faces the first surface of the first terminal.

3. The device of claim 1 wherein the second source is fabricated on a second source terminal having a second source terminal surface and wherein the second source terminal surface faces the first surface of the first terminal.

4. The device of claim 1 wherein the second gate is electrically connected to a second gate terminal and wherein at least a portion of the second gate terminal is on a plane that is substantially parallel to a plane of the first terminal.

5. The device of claim 1, wherein the at least a portion of the first gate is a terminal that is substantially on the same plane as the first terminal.

6. The device of claim 1 wherein the first drain is fabricated on a first drain terminal having a first drain terminal surface, wherein the second source is fabricated on a second source terminal having a second source terminal surface, and wherein the first drain terminal surface and the second source terminal surface are substantially on the same plane.

7. The device of claim 6, wherein the first drain terminal and the second source terminal are fabricated from the same material.

8. The device of claim 7, wherein the material is a sheet of copper.

9. The device of claim 6, wherein a portion of the material of the second source is not etched.

10. The device of claim 6, wherein a space between the second source and the second gate is fully etched.

11. A method of fabricating a circuit, the method comprising:
bonding a first drain of a first transistor to a first surface of a first terminal that is at least part of a first lead frame;
bonding a second source of a second transistor to a first surface of a second terminal that is at least part of the first lead frame;
bonding a second drain of the second transistor and a first source of the first transistor to a first surface of a third terminal, wherein the first surface of the third terminal faces both the first surface of the first terminal and the first surface of the second terminal, and wherein the first surface of the third terminal is at least part of a second lead frame; and
bonding a first gate of the first transistor to a first gate terminal, wherein at least a portion of the first gate terminal is on a plane that is at least substantially parallel with a plane of the first surface of the third terminal.

12. The method of claim 11, comprising forming the first terminal and the second terminal from a single sheet of material.

13. The method of claim 11, comprising positioning at least a portion of the first drain and at least a portion of the second source on a substantially common plane.

14. (canceled)

15. The method of claim 11, further comprising bonding a second gate terminal to a second gate, wherein at least a portion of the second gate terminal is on a plane that is at least substantially parallel with a plane of at least one of the first terminal and the second terminal.

16. (canceled)

17. The method of claim 1, further comprising bonding the first lead frame to the second lead frame.

18. The method of claim 11 further comprising bonding the first gate to the first gate terminal forming at least a portion of the second lead frame.

19. The method of claim 15 further comprising fabricating the second gate terminal coupled to the second gate on at least a portion of the first lead frame.

20. A dual transistor device comprising:
a first transistor having a first drain, a first gate, and first source;
a second transistor having a second drain, a second gate, and a second source;
a first terminal fabricated on a first lead frame, the first terminal being substantially flat and having a first surface, wherein the first source is located adjacent a first portion of the first surface and is electrically coupled to the first terminal, and wherein the second drain is located adjacent a second portion of the first surface and is electrically coupled to the first terminal;
a second terminal fabricated on a second lead frame, wherein the first drain is fabricated on the second terminal; and
a third terminal fabricated on the second lead frame, wherein the second source is fabricated on the third terminal.
